(19) United States
(12) Patent Application Publication
(10) Pub. No.: US 2023/0217656 A1
(43) Pub. Date: Jul. 6, 2023

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Jae Hyun HAN, Icheon-si Gyeonggi-do (KR)

(73) Assignee: SK hynix Inc., Icheon-si Gyeonggi-do (KR)

(21) Appl. No.: 17/848,920

(22) Filed: Jun. 24, 2022

(30) Foreign Application Priority Data
Jan. 3, 2022 (KR) 10-2022-0000603

(51) Int. Cl. H01L 27/11582; H01L 27/11556

(52) U.S. Cl. CPC H01L 27/11582; H01L 27/11556

(57) ABSTRACT

The present discloses relates to a semiconductor device and a method of manufacturing the semiconductor device. A semiconductor device includes a stacked structure including insulating layers and conductive layers stacked alternately with each other, a channel structure passing through at least a portion of the stacked structure, and a memory layer interposed between the conductive layers and the channel structure, wherein the memory layer includes a floating gate arranged between the conductive layers and the channel structure.

### CROSS-REFERENCE TO RELATED APPLICATION

The present application claims priority under 35 U.S.C. § 119(a) to Korean patent application number 10-2022-0000603 filed on Jan. 3, 2022, in the Korean Intellectual Property Office, the entire disclosure of which is incorporated by reference herein.

### BACKGROUND

### 1. Technical Field

Various embodiments relate generally to an electronic device, and more particularly, to a semiconductor device and a manufacturing method of the semiconductor device.

### 2. Related Art

Non-volatile memory devices retain stored data regardless of power on/off conditions. The increase in integration density of two-dimensional non-volatile memory devices in which memory cells are formed in a single layer over a substrate has recently been limited. Thus, three-dimensional non-volatile memory devices have been proposed in which memory cells are stacked in a vertical direction over a substrate.

A three-dimensional non-volatile memory device may include interlayer insulating layers and gate electrodes stacked alternately with each other, and channel layers passing therethrough, with memory cells stacked along the channel layers. Various structures and manufacturing methods have been developed to improve the operational reliability of three-dimensional non-volatile memory devices.

### SUMMARY

According to an embodiment, a semiconductor device may include a stacked structure including insulating layers and conductive layers stacked alternately with each other, a channel structure passing through at least a portion of the stacked structure, and a memory layer interposed between the conductive layers and the channel structure, wherein the memory layer includes a floating gate arranged between the conductive layers and the channel structure.

According to an embodiment, a method of manufacturing a semiconductor device may include forming a hole passing through at least a portion of a stacked structure including first material layers and second material layers stacked alternately with each other, forming insulating patterns on sidewalls of the first material layers exposed through the hole to form a concave region between the insulating patterns, forming a blocking insulating layer, a charge trap layer, and a floating gate sequentially in the concave region to bury the concave region, forming a tunnel isolation layer and a channel layer sequentially along a sidewall of the hole, and replacing the second material layers with conductive layers.

### BRIEF DESCRIPTION OF THE DRAWINGS

FIG. I. is a diagram illustrating the configuration of a semiconductor device according to an embodiment of the present disclosure;

FIGS. 2A and 2B are diagrams illustrating a band gap energy of a memory cell included in a semiconductor device according to an embodiment of the present disclosure;

FIGS. 3A, 3B, 3C, 3D, and 3E are diagrams illustrating a method of manufacturing a semiconductor device according to an embodiment of the present disclosure;

FIG. 4 is a diagram illustrating the configuration of a semiconductor device according to another embodiment of the present disclosure;

FIG. 5 is a diagram illustrating the configuration of a semiconductor device according to another embodiment of the present disclosure;

FIG. 6 is an enlarged view of an area A of FIG. 5;

FIGS. 7A, 713, 7C, 7D, 7E, 7F, and 7G are diagrams illustrating a method of manufacturing a semiconductor device according to another embodiment of the present disclosure;

FIG. 8 is a block diagram illustrating the configuration of a memory system according to an embodiment of the present disclosure;

FIG. 9 is a block diagram illustrating the configuration of a memory system according to an embodiment of the present disclosure;

FIG. 10 is a block diagram illustrating the configuration of a computing system according to an embodiment of the present disclosure; and

FIG. 11 is a block diagram illustrating a computing system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, embodiments of the present disclosure will be described in detail with reference to the accompanying drawings in order for those skilled in the art to be able to readily implement the technical spirit of the present disclosure.

Various embodiments are directed to a semiconductor device having a stabilized structure and improved characteristics, and a method of manufacturing the semiconductor device.

FIG. 1 is a diagram illustrating the configuration of a semiconductor device according to an embodiment of the present disclosure.

Referring to FIG. 1, a semiconductor device according to an embodiment of the present disclosure may include a stacked structure ST, a hard mask pattern HM, a channel structure CH, and a memory layer ML.

The stacked structure ST may include conductive layers 11 and insulating layers 12 that are stacked alternately with each other. The conductive layers 11 may be gate electrodes of a select transistor, a memory cell, and the like. The conductive layers 11 may be a select line coupled to the select transistor, a word line coupled to the memory cell, and the like. The conductive layers 11 may include a conductive material such as polysilicon, tungsten, metal, or the like. The insulating layers 12 may be provided to insulate the stacked conductive layers 11 from each other. The insulating layers 12 may include an insulating material such as oxides and nitrides.

The hard mask pattern HM may be located over the stacked structure ST. The hard mask pattern HM may include a material having an etch selectivity with respect to the insulating layers 12. The hard mask pattern HM may include nitride, a carbon-based material, or a combination thereof, According to an embodiment of the present disclosure, the hard mask pattern HM may be disposed over the stacked structure ST, However, the insulating layer 12 may replace the hard mask pattern HM.

The channel structure CH may at least partially pass through the stacked structure ST and the hard mask pattern HM. The channel structure CH may extend in a direction in which the conductive layers 11 and the insulating layers 12 are stacked on top of each other. The stacking direction may be referred to as a second direction II. The second direction II may be vertical with respect to a substrate (not shown), A first direction I may be horizontal with respect to the substrate. The channel structure CH may extend in the vertical direction with respect to the substrate. The channel structure CH may include a channel layer 13 and may further include at least one of a gap-filling layer 14 and a capping layer 15, The channel layer 13 may refer to a region where a channel of the select transistor and the memory cell is formed. The channel layer 13 may include a semiconductor material, such as silicon or germanium, or a nanostructure, such as nanodots, nanotubes, or grapheme. The gap-filling layer 14 may be formed in the channel layer 13 and include an insulating material such as oxides. The capping layer 15 may be coupled to the channel layer 13 and include a conductive material such as polysilicon.

A memory layer ML may be interposed between the stacked structure ST and the channel structure CH and may fill space between the conductive layers 11 and the channel structure CH. The memory layer ML may include a blocking insulating layer BI, a charge trap layer CT, a floating gate FG, and a tunnel isolation layer TI. The tunnel isolation layer TI may surround a sidewall of the channel structure CH. The tunnel isolation layer TI may be a layer where charges are tunneled by Fowler-Nordheim (F-N) tunneling, and may include an insulating material, such as oxides or nitrides. The blocking insulating layer B1, the charge trap layer CT, and the floating gate FG may be arranged in space defined between the insulating layers 12 adjacent to each other in the stacking direction and space defined between the conductive layers 11 and the channel structure CH. The floating gate FG may have a first sidewall corresponding to an inner wall which contacts the tunnel isolation layer TI and a second sidewall corresponding to an outer wall which contacts the conductive layers 11. The floating gate FG may trap charges introduced by the tunneling of the tunnel isolation layer TI during a program operation, The floating gate FG may include polysilicon. The charge trap layer CT may surround the second sidewall of the floating gate FG and upper and lower surfaces thereof adjacent to the insulating layers 12. The charge trap layer CT may include a plurality of trap sites, During a program operation, some of the charges in the floating gate FG may be trapped in the trap sites of the charge trap layer CT. The charge trap layer CT may include either or both of a chalcogenide compound and a metal compound. The charge trap layer CT may have a smaller thickness than the floating gate FG. The thickness of the charge trap layer CT may be controlled so that the amount of charges trapped in the charge trap layer CT might not affect the program and erase operations, The blocking insulating layer BI may be arranged between the charge trap layer CT and the conductive layers 11 and surround the outer wall of the charge trap layer CT. The blocking insulating layer BI may prevent or mitigate the charges trapped in the floating gate FG and the charge trap layer CT from moving to the conductive layer 11, and may include a high-k material such as aluminum oxide (Al₂O₃), hafnium oxide (HfOx), and hafnium silicon oxide (HfSiOx).

According to the above structure, memory cells or select transistors may be located at intersections between the channel structure CH and the conductive layers 11. Memory cells and select transistors sharing the channel structure CH may form one memory string. A memory string may include at least one drain select transistor, memory cells, and at least one source select transistor.

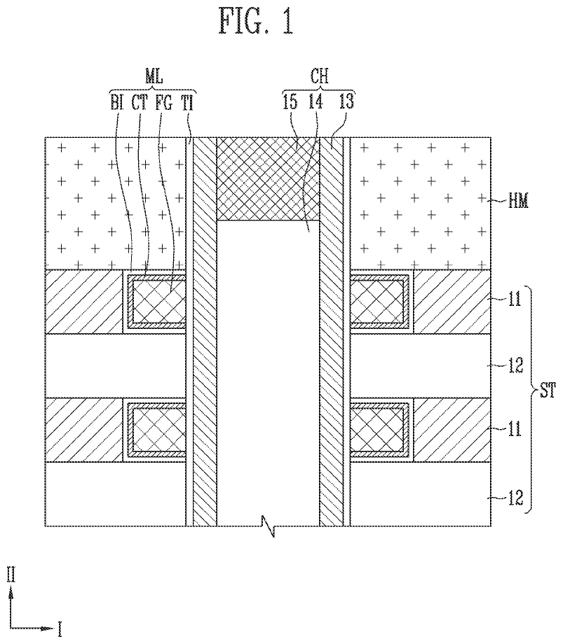

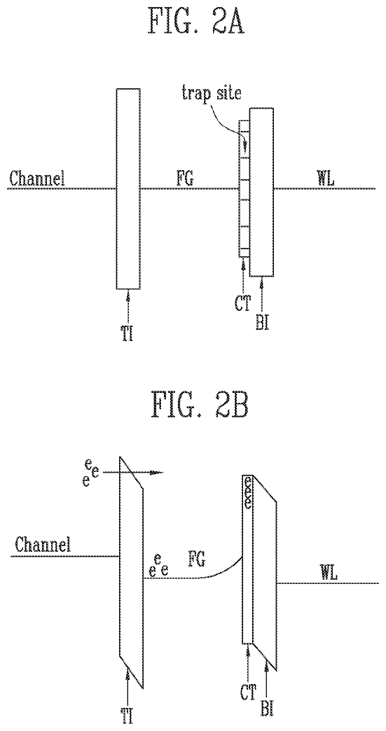

FIGS. 2A and 2B are diagrams illustrating a band gap energy of a memory cell included in a semiconductor device according to an embodiment of the present disclosure.

FIG. 2A shows a band gap energy of a memory cell in which a voltage is not applied to a word line WL. The charge trap layer CT which surrounds the upper and lower surfaces and the outer wall of the floating gate FG may include a plurality of trap sites.

FIG. 2B shows a band gap energy of a memory cell in which a program voltage is applied to the word line WL. When the program voltage is applied to the word line WL, charges (e) from the channel may tunnel the tunnel isolation layer TI and flow into the floating gate FG. The charges (e) in the floating gate FG may be trapped in the trap sites of the charge trap layer CT. As a result, a high charge barrier may be formed between the floating gate FG and the blocking insulating layer BI by the charges (e) trapped in the charge trap layer CT. Therefore, even when a high program voltage is applied, the charges (e) in the floating gate FG might not leak in a direction of the blocking insulating layer BI. In other words, the charges (e) may be stably stored in the floating gate FG by the charge barrier generated by the charge trap layer CT. As a result, in an embodiment, leakage of charges stored in the memory cell may be prevented or mitigated to thereby improve data retention characteristics of the semiconductor device.

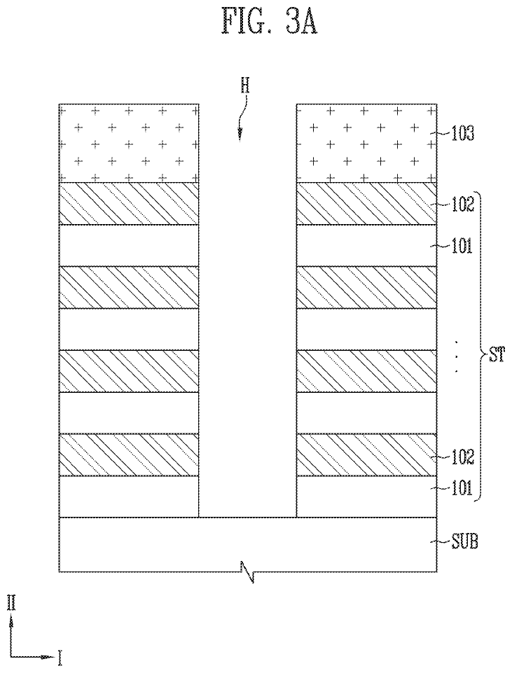

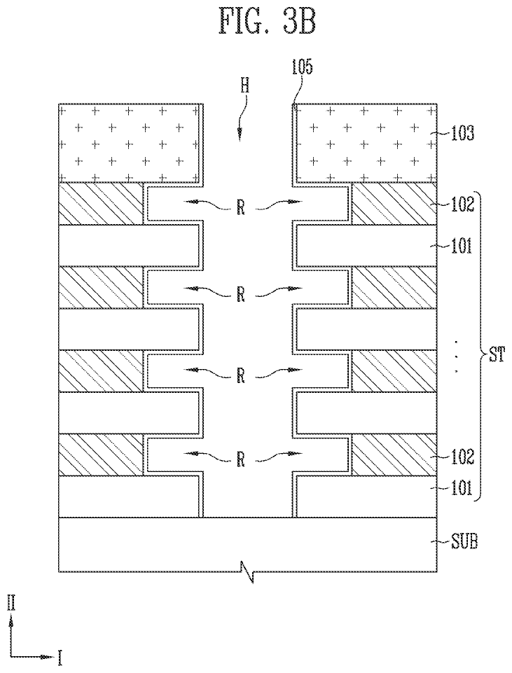

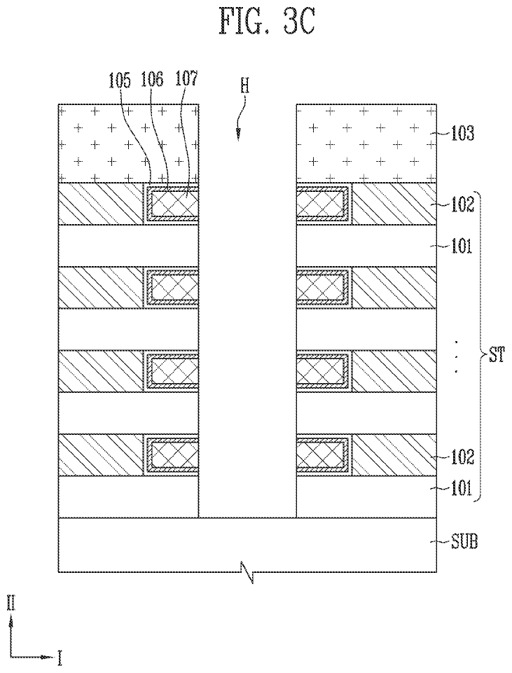

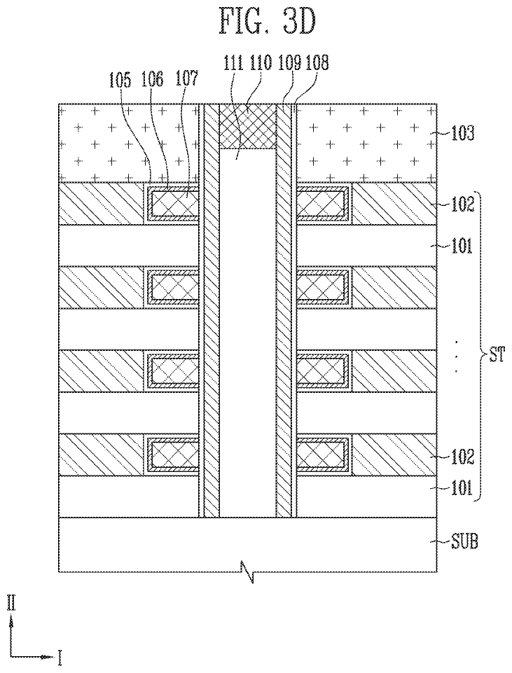

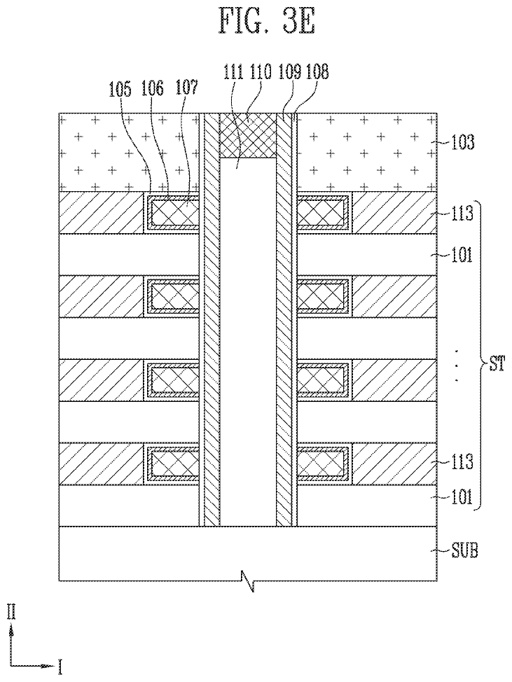

FIGS. 3A to 3E are diagrams illustrating a method of manufacturing a semiconductor device according to an embodiment of the present disclosure.

Referring to FIG. 3A, the stacked structure ST may be formed on a substrate SUB. The stacked structure ST may include first material layers 101 and second material layers 102 that are staked alternately with each other. The first and second material layers 101 and 102 may be stacked in the second direction II vertical to the substrate SUB. The first and second material layers 101 and 102 may be formed using a deposition process such as Chemical Vapor deposition (CVD).

The first material layers 101 may include a material having a high etch selectivity with respect to the second material layers 102. For example, the first material layers 101 may include an insulating material such as oxides and the second material layers 102 may include a sacrificial material such as nitrides. In another example, the first material layers 101 may include an insulating material such as oxides and the second material layers 102 may include a conductive material such as polysilicon and tungsten.

Subsequently, a hard mask pattern 103 may be formed on the stacked structure ST. The hard mask pattern 103 may include a material having an etch selectivity with respect to the second material layers 102. The hard mask pattern 103 may include nitride, a carbon-based material, or a combination thereof, In another embodiment, the hard mask pattern 103 may include the same material as the first material layers 101.

By performing an etch mask using the hard mask pattern 103 as an etch mask, a hole H which passes through at least a portion of the stacked structure ST may be formed. The hole H may be partially extended into the substrate SUB.

Referring to FIG. 3B, recess regions R may be formed by etching the second material layers 102 exposed through the hole H to a predetermined depth in a horizontal direction. In other words, sidewalk of the second material layers 102 may be etched to a predetermined depth so that the first material layers 101 may protrude more than the second material layers 102.

A blocking insulating layer 105 may be formed along surfaces of the hole H and the recess regions R. The blocking insulating layer 105 may include a high-k material such as aluminum oxide (Al₂O₃), hafnium oxide (HfOx), and hafnium silicon oxide (HfSiOx).

Referring to FIG. 3C, a charge trap layer 106 may be formed on a surface of the blocking insulating layer 105. The charge trap layer 106 may include either or both of a chalcogenide compound and a metal compound. A floating gate 107 may be formed to bury the recess region R of FIG. 3B, The floating gate 107 may include polysilicon.

By performing an etch process, the blocking insulating layer 105, the charge trap layer 106, and the floating gate 107 formed on a sidewall of the first material layer 101 may be removed. As a result, the blocking insulating layer 105, the charge trap layer 106, and the floating gate 107 formed in each recess region R of FIG. 3B may be physically separated from the blocking insulating layer 105, the charge trap layer 106, and the floating gate 107 formed in the corresponding recess region R adjacent thereto.

Referring to FIG. 3D, a tunnel isolation layer 108 may be formed on a sidewall of the hole H of FIG. 3C. The tunnel isolation layer 108 may be a layer where charges are tunneled by Fowler-Nordheim (F-N) tunneling, and may include an insulating material, such as oxide or nitride.

A channel layer 109 may be formed on a sidewall of the tunnel isolation layer 108. The channel layer 109 may include a semiconductor material. According to an embodiment, the channel layer 109 may include a semiconductor material, such as silicon or germanium, or a nanostructure, such as nanodots, nanotubes, or graphene.

A gap-filling layer 111 may fill a central portion of the hole H. Further, a predetermined area of an upper portion of the gap-filling layer 111 may be etched, and a capping layer 110 may be formed in the space from which the gap-filling layer 111 is removed.

Referring to FIG. 3E, the second material layers 102 of FIG. 3D may be replaced by third material layers 113. For example, when the second material layers include a sacrificial material and the first material layers 101 include an insulating material, the second material layers 102 may be replaced by conductive layers. The third material layers 113 may include a conductive material such as polysilicon, tungsten, metal, or the like,

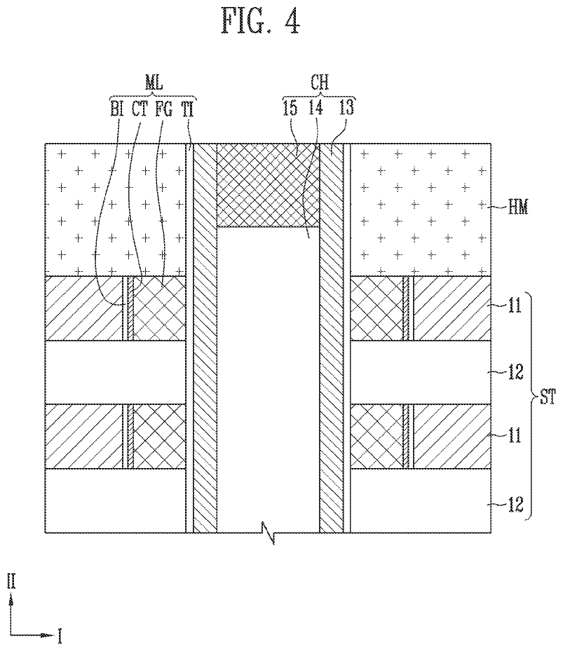

FIG. 4 is a diagram illustrating the configuration of a semiconductor device according to another embodiment of the present disclosure.

Referring to FIG. 4, a semiconductor device according to another embodiment of the present disclosure may include the stacked structure ST, the hard mask pattern HM, the channel structure CH, and the memory layer ML.

The stacked structure ST may include the conductive layers 11 and the insulating layers 12 that are stacked alternately with each other. The conductive layers 11 may be gate electrodes of a select transistor, a memory cell, and the like. The conductive layers 11 may be a select line coupled to the select transistor, a word line coupled to the memory cell, and the like. The conductive layer 11 may include a conductive material such as polysilicon, tungsten, metal, or the like. The insulating layers 12 may be provided to insulate the stacked conductive layers 11 from each other, The insulating layers 12 may include an insulating material such as oxides and nitrides.

The hard mask pattern HM may be located over the stacked structure ST. The hard mask pattern HM may include a material having an etch selectivity with respect to the insulating layers 12, The hard mask pattern HM may include nitride, a carbon-based material, or a combination thereof.

The channel structure CH may pass through at least a portion of the stacked structure ST and the hard mask pattern HM. The channel structure CH may extend in a direction in which the conductive layers 11 and the insulating layers 12 are stacked on top of each other. The channel structure CH may include the channel layer 13 and may further include at least one of the gap-filling layer 14 and the capping layer 15. The channel layer 13 may refer to a region where a channel of a select transistor and a memory cell is formed, The channel layer 13 may include a semiconductor material, such as silicon or germanium, or a nanostructure, such as nanodots, nanotubes, or graphene. The gap-filling layer 14 may be formed in the channel layer 13 and include an insulating material such as oxides. The capping layer 15 may be coupled to the channel layer 13 and include a conductive material such as polysilicon.

The memory layer ML may be interposed between the stacked structure ST and the channel structure CH and fill space between the conductive layers 11 and the channel structure CH. The memory layer ML may include the blocking insulating layer BI, the charge trap layer CT, the floating gate FG, and the tunnel isolation layer TI. The tunnel isolation layer TI may surround a sidewall of the channel structure CH. The tunnel isolation layer TI may be a layer where charges are tunneled by Fowler-Nordheim (F-N) tunneling, and may include an insulating material, such as oxides or nitrides. The blocking insulating layer BI, the charge trap layer CT, and the floating gate FG may be arranged in space between the insulating layers 12 adjacent to each other in the stacking direction and space between the conductive layers 11 and the channel structure CH. The blocking insulating layer BI, the charge trap layer CT, and the floating gate FG may be sequentially arranged between the conductive layers 11 and the tunnel isolation layer TI. For example, the blocking insulating layer BI may be formed in a liner type on sidewalk of the conductive layers 11, the charge trap layer CT may be arranged in a liner type on a sidewall of the blocking insulating layer BI, and the floating gate FG may be arranged between the charge trap layer CT and the tunnel isolation layer TI. In other words, a second sidewall of the floating gate FG which corresponds to an outer wall thereof may contact the charge trap layer CT, and a first sidewall thereof corresponding to an inner wall may contact the tunnel isolation layer TI. In addition, upper and lower surfaces of the floating gate FG may contact the insulating layer 12.

The floating gate FG may include polysilicon. The charge trap layer CT may include either or both of a chalcogenide compound and a metal compound. The blocking insulating layer BI may include a high-k material such as aluminum oxide (Al₂O₃), hafnium oxide (HfOx), and hafnium silicon oxide (HfSiOx).

According to the above structure, memory cells or select transistors may be located at intersections between the channel structure CH and the conductive layers 11. Memory cells and select transistors that share the channel structure CH may form one memory string. A memory string may include at least one drain select transistor, memory cells, and at least one source select transistor.

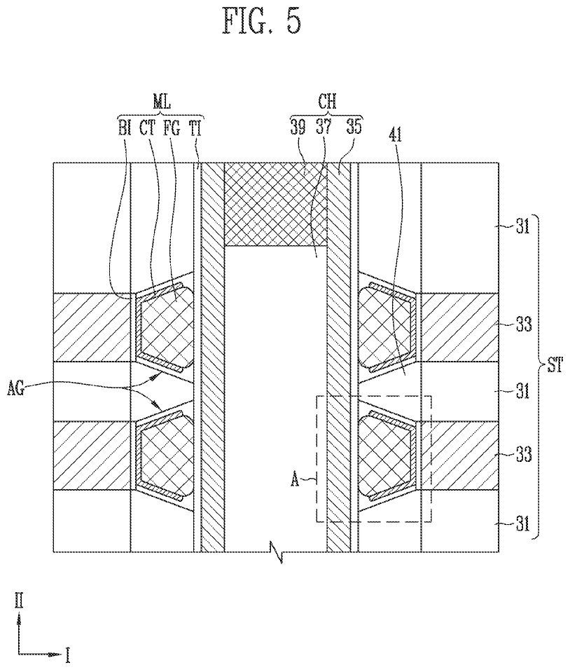

FIG. 5 is a diagram illustrating the configuration of a semiconductor device according to another embodiment of the present disclosure.

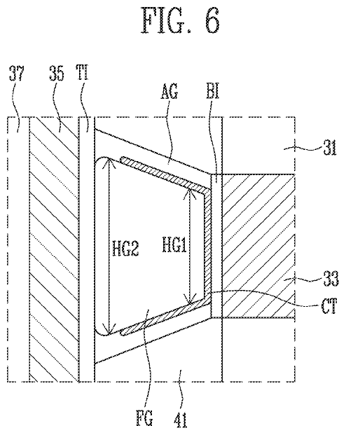

FIG. 6 is an enlarged view of an area A of FIG. 5.

Referring to FIGS. 5 and 6, a semiconductor device according to another embodiment of the present disclosure may include the stacked structure ST, the channel structure CH, the memory layer ML, and an insulating pattern 41.

The stacked structure ST may include conductive layers 33 and insulating layers 31 that are stacked alternately with each other. The conductive layers 33 may be gate electrodes of a select transistor, a memory cell, and the like. The conductive layers 33 may be a select line coupled to a select transistor, a word line coupled to a memory cell, and the like, The conductive layer 33 may include a conductive material such as polysilicon, tungsten, metal, or the like. The insulating layers 31 may be provided to insulate the stacked conductive layers 33 from each other. The insulating layers 31 may include an insulating material such as oxides and nitrides.

The channel structure CH may pass through at least a portion of the stacked structure ST. The channel structure CH may extend in a direction in which the conductive layers 33 and the insulating layers 31 are stacked on top of each other. The stacking direction may be the second direction II. The second direction II may be vertical with respect to a substrate (not shown). The first direction I may be horizontal with respect to the substrate. The channel structure CH may extend in the vertical direction with respect to the substrate. The channel structure CH may include a channel layer 35 and further include at least one of a gap-filling layer 37 and a capping layer 39. The channel layer 35 may refer to a region where a channel of a select transistor and a memory cell is formed. The channel layer 35 may include a semiconductor material, such as silicon or germanium, or a nanostructure, such as nanodots, nanotubes, or graphene. The gap-filling layer 37 may be formed in the channel layer 35 and include an insulating material such as oxides. The capping layer 39 may be coupled to the channel layer 35 and include a conductive material such as polysilicon.

The memory layer ML may be interposed between the stacked structure ST and the channel structure CH and fill space between the conductive layers 33 and the channel structure CH. The memory layer ML may include the blocking insulating layer BI, the charge trap layer CT, the floating gate FG, and the tunnel isolation layer TI. The tunnel isolation layer TI may surround a sidewall of the channel structure CH. The tunnel isolation layer TI may be a layer where charges are tunneled by Fowler-Nordheim (F-N) tunneling, and may include an insulating material, such as oxides or nitrides, The blocking insulating layer BI, the charge trap layer CT, and the floating gate FG may be arranged between the conductive layers 33 and the channel structure CH. The floating gate FG may have a first sidewall corresponding to an inner wall which contacts the tunnel isolation layer TI and a second sidewall corresponding to an outer wall which contacts the conductive layers 33. A first sidewall length HG2 of the floating gate FG may be greater than a second sidewall length HG1. The floating gate FG may have a trapezoidal shape. An edge region of the first sidewall of the floating gate FG may have a round shape. The floating gate FG may trap charges introduced by the tunneling of the tunnel isolation layer TI during a program operation. The floating gate FG may include polysilicon. The charge trap layer CT may surround the second sidewall and the upper and lower surfaces of the floating gate FG. The charge trap layer CT may include a plurality of trap sites. During a program operation, some of the charges in the floating gate FG may be trapped in the trap sites of the charge trap layer CT. The charge trap layer CT may include either or both of a chalcogenide compound and a metal compound. The blocking insulating layer BI may be arranged between the charge trap layer CT and the conductive layers 33. The blocking insulating layer BI may prevent or mitigate the charges trapped in the floating gate FG and the charge trap layer CT from moving to the conductive layer 33, and may include a high-k material such as aluminum oxide (Al₂O₃), hafnium oxide (HfOx), and hafnium silicon oxide (HfSiOx).

An insulating pattern 41 may be arranged in space between adjacent floating gates FG. For example, the insulating pattern 41 may be arranged in space defined between the channel structure CH and the insulating layers 31 and between the floating gates FG. The insulating pattern 41 may include oxides.

An air gap AG may be arranged in space between the insulating pattern 41 and the floating gates FG. The air gap AG may be interposed between the insulating pattern 41 and the charge trap layer CT surrounding the upper and lower surfaces of the floating gate FG.

According to the above structure, memory cells or select transistors may be located at intersections between the channel structure CH and the conductive layers 33, Memory cells and select transistors that share the channel structure CH may form one memory string. A memory string may include at least one drain select transistor, memory cells, and at least one source select transistor.

According to another embodiment of the present disclosure as described above, the floating gate FG may have a trapezoidal shape to cause an increase in volume. Therefore, in an embodiment, the number of charges to be stored may be increased, In addition, in an embodiment, the edge region of the first sidewall of the floating gate FG may have a round shape, so that an electric field (E-field) may be dispersed, In addition, in an embodiment, the air gap AG may be disposed in the space between adjacent floating gates FG, so that an interference phenomenon between the floating gates FG may be improved.

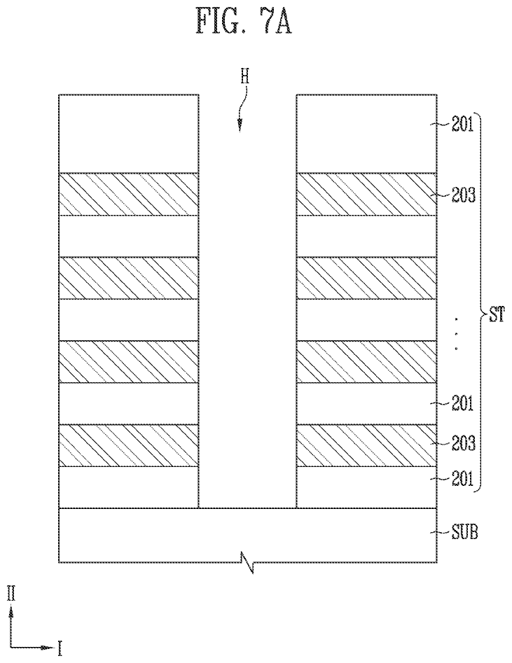

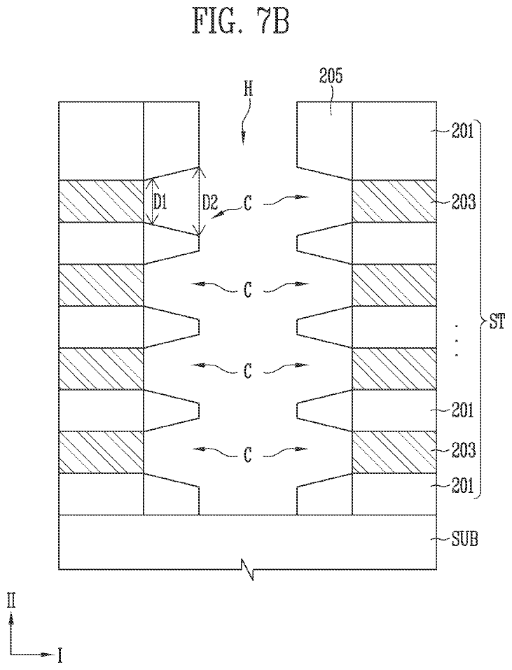

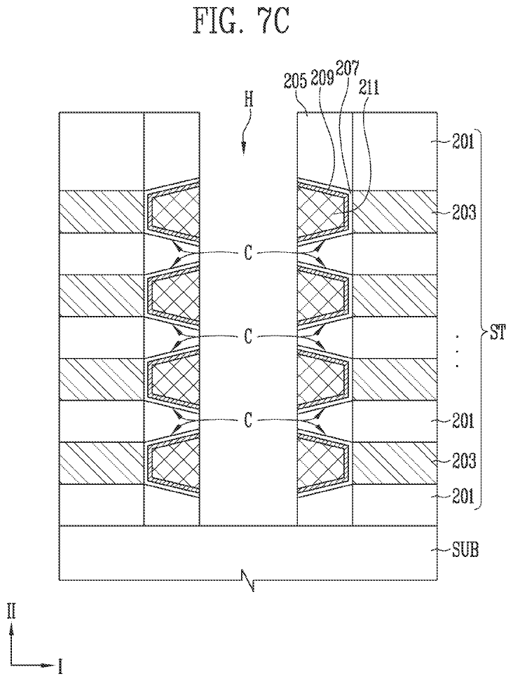

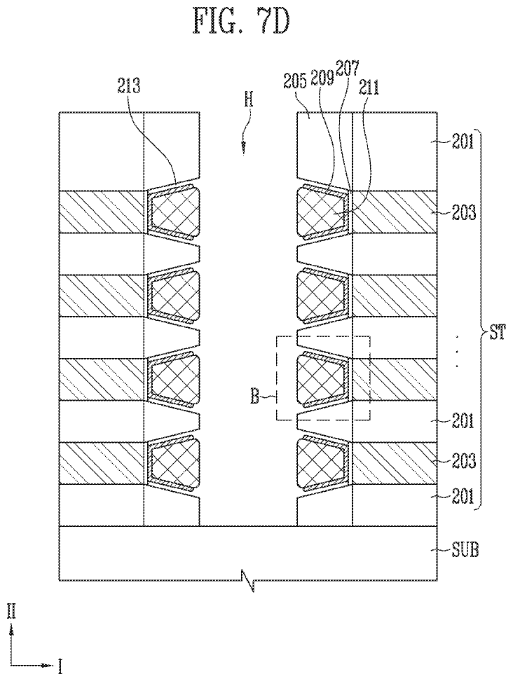

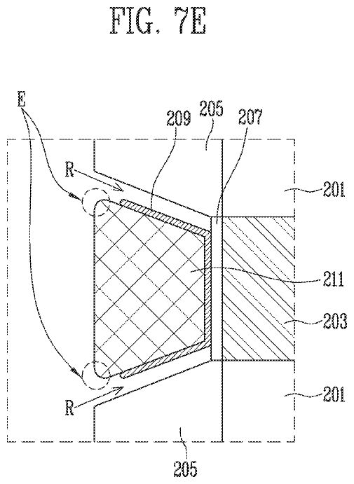

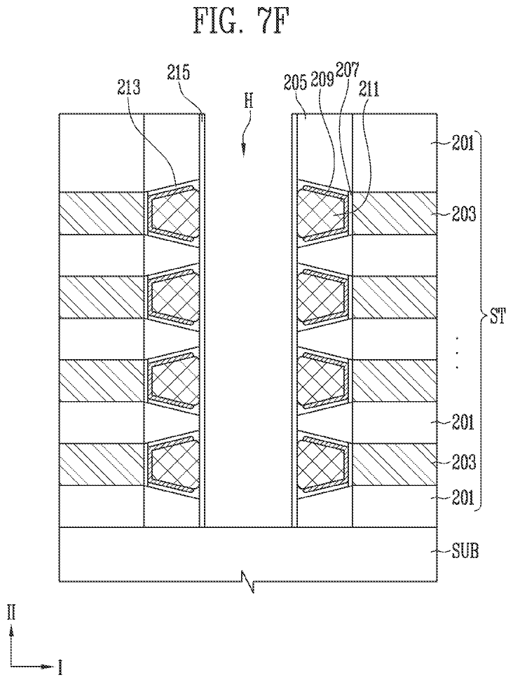

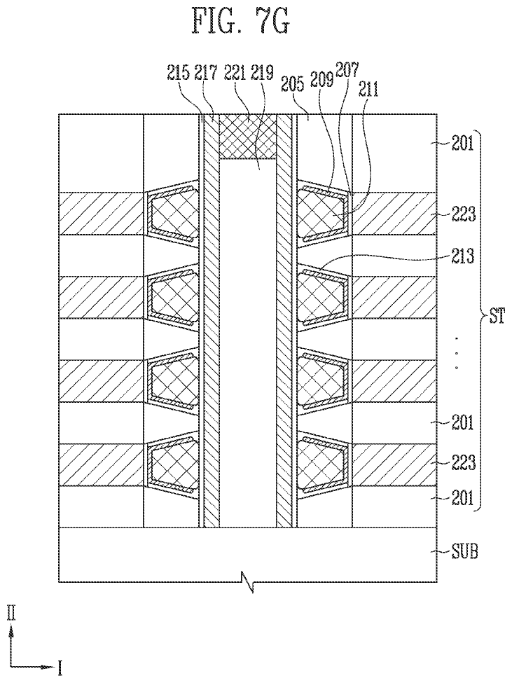

FIGS. 7A to 7G are diagrams illustrating a method of manufacturing a semiconductor device according to another embodiment of the present disclosure.

Referring to FIG. 7A, the stacked structure ST may be formed on the substrate SUB. The stacked structure ST may include first material layers 201 and second material layers 203 that are staked alternately with each other. The first and second material layers 201 and 203 may be stacked in the second direction II vertical to the substrate SUB. The first and second material layers 201 and 203 may be formed using a deposition process such as Chemical Vapor deposition (CVD).

The first material layers 201 may include a material having a high etch selectivity with respect to the second material layers 203. For example, the first material layers 201 may include an insulating material such as oxide and the second material layers 203 may include a sacrificial material such as nitride. In another example, the first material layers 201 may include an insulating material such as oxides and the second material layers 203 may include a conductive material such as polysilicon and tungsten.

The hole H may be formed through the stacked structure ST. The hole H may be partially extended into the substrate SUB.

Referring to FIG. 7B, insulating patterns 205 may be formed on sidewalls of the first material layers 201 which are exposed through the hole H. The insulating patterns 205 may be formed on the sidewalk of the first material layers using a selective oxidation process. The insulating patterns 205 may include oxides.

Concave regions C may be defined between the insulating patterns 205 which are adjacent to each other in the second direction II. A length D1 of a bottom surface of the concave region C which contacts the second material layer 203 may be smaller than a length D2 of an opening of the concave region C.

Referring to FIG. 7C, a blocking insulating layer 207, a charge trap layer 209, and a floating gate 211 may be formed on surfaces of the hole H and the concave regions C. The concave regions C may be completely buried in the floating gate 211.

The blocking insulating layer 207 may include a high-k material such as aluminum oxide (Al₂O₃), hafnium oxide (HfOx), and hafnium silicon oxide (HfSiOx). The charge trap layer 209 may include either or both of a chalcogenide compound and a metal compound. The floating gate 211 may include polysilicon.

An etch process may be performed to remove the floating gate 211, the charge trap layer 209, and the blocking insulating layer 207 formed on sidewalls of the insulating patterns 205. The blocking insulating layer 207, the charge trap layer 209, and the floating gate 211 formed in each concave region C may be physically separated from the blocking insulating layer 207, the charge trap layer 209, and the floating gate 211 formed in an adjacent concave region C. In addition, the floating gate 211 may have a trapezoidal shape and be formed in the concave region C.

Referring to FIG. 7D, the blocking insulating layer 207 may be etched to a predetermined depth and exposed such that the blocking insulating layer 207 may remain on only the sidewall of the second material layer 203. An edge of the exposed surface of the floating gate 211 may be etched together during an etch process, and may have a round shape.

FIG. 7E is an enlarged view of an area B of FIG. 7D. Referring to FIG. 7E, the recess region R may be formed in space between the insulating pattern 205 and the charge trap layer 209 by the etch process of the above-described blocking insulating layer 207, In addition, an edge region E of the floating gate 211 may have a round shape.

Referring to FIG. 7F, a tunnel isolation layer 215 may be formed along a sidewall of the floating gate 211 and a sidewall of the insulating pattern 205. Therefore, the recess region R of FIG. 7E might not be buried and an opening thereof may be closed by the tunnel isolation layer 215 to thereby form an air gap 213, In other words, the air gap 213 may be arranged between the insulating pattern 205 and the charge trap layer 209. The tunnel isolation layer 215 may be a layer where charges are tunneled by Fowler-Nordheim (F-N) tunneling, and may include an insulating material, such as oxide or nitride.

According to another embodiment, the recess region R of FIG. 7E may be buried by a low dielectric layer before the tunnel isolation layer 215 is formed.

Referring to FIG. 7G, a channel layer 217 may be formed on a sidewall of the tunnel isolation layer 215. The channel layer 217 may include a semiconductor material, According to an embodiment, the channel layer 217 may include a semiconductor material, such as silicon or germanium, or a nanostructure, such as nanodots, nanotubes, or graphene.

A gap-filling layer 219 may fill a central portion of the hole H. Further, a predetermined area of an upper portion of the gap-filling layer 219 may be etched, and a capping layer 221 may be formed in space from which the gap-filling layer 219 is removed.

The second material layer 203 of FIG. 7G may be replaced by a third material layer 223. For example, when the second material layers include a sacrificial material and the first material layers 201 include an insulating material, the second material layers may be replaced by conductive layers. The third material layers 223 may include a conductive material such as polysilicon, tungsten, metal, or the like.

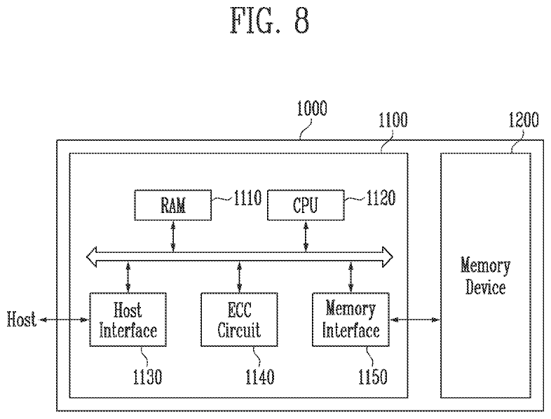

FIG. 8 is a block diagram illustrating a memory system 1000 according to an embodiment of the present disclosure.

As illustrated in FIG. 8, the memory system 1000 according to an embodiment may include a memory device 1200 and a controller 1100.

The memory device 1200 may be used to store various types of data such as text, graphics, and software codes. The memory device 1200 may be a non-volatile memory device. In addition, the memory device 1200 may include the above configuration described with reference to FIG. 1, 4, or 5, and may be manufactured by the method described with reference to FIGS. 3A to 3E or the method described with reference to FIGS. 7A to 7G. Since the memory device 1200 is configured and manufactured in the same manner as described above, a detailed description thereof will be omitted.

The controller 1100 may be coupled to a host and the memory device 1200 and configured to access the memory device 1200 in response to a request from the host. For example, the controller 1100 may control read, write, erase, and background operations of the memory device 1200.

The controller 1100 may include a random access memory (RAM) 1110, a central processing unit (CPU) 1120, a host interface 1130, an error correction code (ECC) circuit 1140, and a memory interface 1150.

The RAM 1110 may serve as an operation memory of the CPU 1120, a cache memory between the memory device 1200 and the host, and a buffer memory between the memory device 1200 and the host. For reference, the RAM 1110 may be replaced with a static random access memory (SRAM), a read only memory (ROM), or the like.

The CPU 1120 may control the overall operation of the controller 1100. For example, the CPU 1120 may operate firmware such as a flash translation layer (FTL) stored in the RAM 1110.

The host interface 1130 may interface with the host, For example, the controller 1100 may communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, and an integrated drive electronics (IDE) protocol, a private protocol, and the like.

The ECC circuit 1140 may use an error correction code (ECC) to detect and correct errors in data read from the memory device 1200.

The memory interface 1150 may interface with the memory device 1200. For example, the memory interface 1150 may include a NAND interface or a NOR interface.

For reference, the controller 1100 may further include a buffer memory (not shown) for temporarily storing data. The buffer memory may be used to temporarily store data to be transferred from the host interface 1130 to an external device or data to be transferred from the memory interface 1150 to the memory device 1200, In addition, the controller 1100 may further include a ROM that stores code data for interfacing with the host.

Since the memory system 1000 according to the embodiment includes the memory device 1200 having improved integration density and characteristics, the memory system 1000 may also have improved integration density and characteristics accordingly.

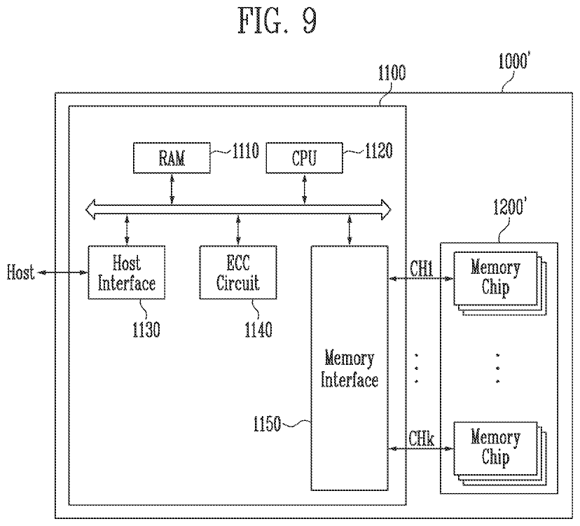

FIG. 9 is a block diagram illustrating the configuration of a memory system 1000′ according to an embodiment of the present disclosure. Hereinafter, any repetitive detailed description of components already mentioned above will be omitted.

Referring to FIG. 9, the memory system 1000′ according to an embodiment of the present disclosure may include a memory device 1200′ and the controller 1100. The controller 1100 may include the RAM 1110, the CPU 1120, the host interface 1130, the ECC circuit 1140, and the memory interface 1150.

The memory device 1200′ may be a non-volatile memory device. In addition, the memory device 1200′ may include the above configuration described with reference to FIG. 4, or 5, and may be manufactured by the method described with reference to FIGS. 3A to 3E, or the method described with reference to FIGS. 7A to 7G. Since the memory device 1200′ is configured and manufactured in the same manner as described above, a detailed description thereof will be omitted.

Furthermore, the memory device 1200′ may be a multi-chip package including a plurality of memory chips. The plurality of memory chips may be divided into a plurality of groups, which may communicate with the controller 1100 through first to kth channels CFH to CHk, respectively. In addition, memory chips included in a single group may be configured to communicate with the controller 1100 through a common channel. For reference, the memory system 1000′ may be modified such that each memory chip may be coupled to a corresponding single channel.

As described above, since the memory system 1000′ according to the embodiment includes the memory device 1200′ having improved integration and characteristics, the integration and characteristics of the memory system 1000′ may also be improved. In particular, the memory device 1200′ according to the present embodiment may be formed into a multi-chip package, whereby the data storage capacity and the driving speed thereof may be enhanced.

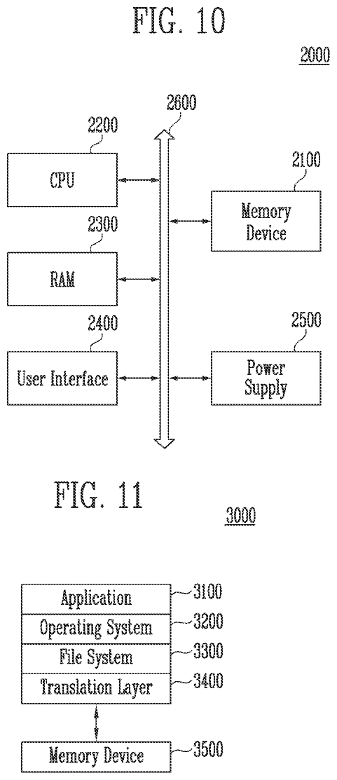

FIG. 10 is a block diagram illustrating the configuration of a computing system 2000 according to an embodiment. Hereinafter, any repetitive detailed description of components already mentioned above will be omitted.

As illustrated in FIG. 10, the computing system 2000 may include a memory device 2100, a CPU 2200, a random-access memory (RAM) 2300, a user interface 2400, a power supply 2500, and a system bus 2600.

The memory device 2100 may store data provided via the user interface 2400, data processed by the CPU 2200, etc. The memory device 2100 may be electrically coupled to the CPU 2200, the RAM 2300, the user interface 2400, and the power supply 2500 by the system bus 2600. For example, the memory device 2100 may be coupled to the system bus 2600 via a controller (not shown), or directly to the system bus 2600. When the memory device 2100 is directly coupled to the system bus 2600, functions of the controller may be performed by the CPU 2200 and the RAM 2300.

The memory device 2100 may be a non-volatile memory. In addition, the memory device 2100 may include the above configuration described with reference to FIG. 1, 4, or 5, and may be manufactured by the method described with reference to FIGS. 3A to 3E, or the method described with reference to FIGS. 7A to 7G. Since the memory device 2100 is configured and manufactured in the same manner as described above, a detailed description thereof will be omitted.

In addition, as described above with reference to FIG. 9, the memory device 2100 may be a multi-chip package composed of a plurality of memory chips.

The computing system 2000 having the above-mentioned configuration may be provided as one of various elements of an electronic device such as a computer, an ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, or the like.

As described above, since the computing system 2000 according to the embodiment includes the memory device 2100 having improved integration and characteristics, the characteristics of the computing system 2000 may also be improved.

FIG. 11 is a block diagram illustrating a computing system 3000 according to an embodiment.

As illustrated in FIG. 11, the computing system 3000 according to an embodiment may include a software layer that has an operating system 3200, an application 3100, a file system 3300, and a translation layer 3400. The computing system 3000 may include a hardware layer such as a memory device 3500.

The operating system 3200 may manage software and hardware resources of the computing system 3000, The operating system 3200 may control program execution of a central processing unit. The application 3100 may include various application programs executed by the computing system 3000. The application 3100 may be a utility executed by the operating system 3200.

The file system 3300 may refer to a logical structure configured to manage data and files present in the computing system 3000. The file system 3300 may organize files or data and store them in the memory device 3500 according to given rules. The file system 3300 may be determined depending on the operating system 3200 used in the computing system 3000. For example, when the operating system 3200 is a Microsoft Windows-based system, the file system 3300 may be a file allocation table (FAT) or an NT file system (NTFS). In addition, when the operating system 3200 is a Unix/Linux system, the file system 3300 may be an extended file system (EXT), a Unix file system (UFS), a journaling file system (JFS), or the like.

FIG. 11 illustrates the operating system 3200, the application 3100, and the file system 3300 in separate blocks. However, the application 3100 and the file system 3300 may be included in the operating system 3200.

The translation layer 3400 may translate an address into a suitable form for the memory device 3500 in response to a request from the file system 3300. For example, the translation layer 3400 may translate a logic address, generated by the file system 3300, into a physical address of the memory device 3500. Mapping information of the logical address and the physical address may be stored in an address translation table. For example, the translation layer 3400 may be a flash translation layer (FTL), a universal flash storage link layer (ULL), or the like.

The memory device 3500 may be a non-volatile memory. In addition, the memory device 3500 may include the above configuration described with reference to FIG. 1, 4, or 5, and may be manufactured by the method described with reference to FIGS. 3A to 3E, or the method described with reference to FIGS. 7A to 7G, Since the memory device 3500 is configured and manufactured in the same manner as described above, a detailed description thereof will be omitted.

The computing system 3000 having the above-described configuration may be divided into an operating system layer that is operated in an upper layer region and a controller layer that is operated in a lower level region, The application 3100, the operating system 3200, and the file system 3300 may be included in the operating system layer, and may be driven by an operating memory of the computing system 3000, The translation layer 3400 may be included in the operating system layer or the controller layer.

As described above, since the computing system 3000 according to the embodiment includes the memory device 3500 having improved integration density and characteristics, characteristics of the computing system 3000 may also be improved.

According to the present disclosure, a semiconductor device having a simplified structure and improved reliability and a method of manufacturing the semiconductor device may be provided.

It will be apparent to those skilled in the art that various modifications can be made to the above-described examples of embodiments of the present disclosure without departing from the spirit or scope of the disclosure. Thus, it is intended that the present disclosure cover all such modifications provided they come within the scope of the appended claims and their equivalents.

What is claimed is:

1. A semiconductor device, comprising:
a stacked structure including insulating layers and conductive layers stacked alternately with each other;
a channel structure passing through at least a portion of the stacked structure; and
a memory layer interposed between the conductive layers and the channel structure,
wherein the memory layer includes a charge trap layer and a floating gate arranged sequentially between the conductive layers and the channel structure.

2. The semiconductor device of claim 1, wherein the insulating layers protrude in a direction toward the channel structure more than the conductive layers, and
wherein the charge trap layer and the floating gate are arranged between the insulating layers.

3. The semiconductor device of claim 2, wherein the charge trap layer surrounds an upper surface and a lower surface of the floating gate adjacent to the insulating layers and an outer wall of the floating gate adjacent to the conductive layers.

4. The semiconductor device of claim 2, wherein the memory layer includes a blocking insulating layer, the charge trap layer, and the floating gate, arranged sequentially between the conductive layers and the channel structure,
wherein the blocking insulating layer is arranged between the insulating layers and
wherein the blocking insulating layer is arranged at an interface between the charge trap layer and the insulating layers and an interface between the charge trap layer and the conductive layers.

5. The semiconductor device of claim 2, wherein the memory layer includes the charge trap layer, the floating gate, and a tunnel isolation layer arranged sequentially between the conductive layers and the channel structure, and
wherein the tunnel isolation layer surrounds a sidewall of the channel structure.

6. The semiconductor device of claim wherein the memory layer includes a blocking insulating layer, the charge trap layer, and the floating gate, arranged sequentially between the conductive layers and the channel structure, and
wherein the floating gate includes polys con and the blocking insulating layer includes a high-k material.

7. The semiconductor device of claim 1, wherein the charge trap layer includes at least one of a chalcogenide compound and a metal compound.

8. A semiconductor device, comprising:
a stacked structure including insulating layers and conductive layers stacked alternately with each other;
a channel structure passing through at least a portion of the stacked structure; and
a memory layer interposed between the conductive layers and the channel structure,
wherein the memory layer includes a floating gate between the conductive layers and the channel structure, and
wherein the floating gate has substantially a trapezoidal shape.

9. The semiconductor device of claim 8, further comprising insulating patterns protruding from side walls of the insulating layers in a direction toward the channel structure, wherein the insulating patterns are closer to the channel structure than the conductive layers in a horizontal direction,
wherein the charge trap layer and the floating gate are arranged in space between the insulating patterns.

10. The semiconductor device of claim 9, further comprising an air gap arranged between the insulating patterns and the memory layer.

11. The semiconductor device of claim 8, wherein a length of a first sidewall of the floating gate adjacent to the channel structure is greater than a length of a second sidewall of the floating gate adjacent to the conductive layers.

12. The semiconductor device of claim 11, wherein an edge region of the first sidewall of the floating gate has substantially a round shape.

13. The semiconductor device of claim 8, wherein the memory layer includes a charge trap layer and the floating gate between the conductive layers and the channel structure, and wherein the charge trap layer surrounds a top surface and a bottom surface of the floating gate and an outer wall of the floating gate adjacent to the conductive layers.

14. The semiconductor device of claim 8, wherein the memory layer includes a charge trap layer and the floating gate between the conductive layers and the channel structure, and wherein the charge trap layer includes at least one of a chalcogenide compound and a metal compound.

15. The semiconductor device of claim 8, wherein the memory layer includes a blocking insulating layer, a charge trap layer, and the floating gate between the conductive layers and the channel structure, and
wherein the blocking insulating layer is arranged at an interface between the charge trap layer and the conductive layers.

16. A method of manufacturing a semiconductor device, the method comprising:
forming a hole passing through at least a portion of a stacked structure including first material layers and second material layers stacked alternately with each other;
forming insulating patterns on sidewalls of the first material layers exposed through the hole to form a concave region between the insulating patterns;
forming a blocking insulating layer, a charge trap layer, and a floating gate sequentially in the concave region to bury the concave region;
forming a tunnel isolation layer and a channel layer sequentially along a sidewall of the hole; and
replacing the second material layers with conductive layers.

17. The method of claim 16, wherein the charge trap layer includes at least one of a chalcogenide compound and a metal compound.

18. The method of claim 16, wherein the concave region has substantially a trapezoidal shape in which a length of an opening is greater than a length of sidewalk of the second material layers.

19. The method of claim 16, further comprising, after the forming of the blocking insulating layer, the charge trap layer, and the floating gate sequentially in the concave region, forming a recess region by etching the blocking insulating layer between the insulating patterns and the charge trap layer.

20. The method of claim 19, wherein in the forming of the recess region, an edge region of an outer wall of the floating gate is etched to have substantially a round shape.
